(19) United States
(12) Patent Application Publication
(10) Pub. No.: US 2026/0237964 A1
(43) Pub. Date: Aug. 13, 2026

(54) OPTICAL MODULE

(71) Applicant: Mitsubishi Electric Corporation, Tokyo (JP)

(72) Inventor: Junichi SUZUKI, Tokyo (JP)

(73) Assignee: Mitsubishi Electric Corporation, Tokyo (JP)

(21) Appl. No.: 19/150,454

(22) PCT Filed: Feb. 17, 2023
(86) PCT No.: PCT/JP2023/005618

§ 371 Date: Jul. 23, 2025

(51) Int. Cl. H01S 5/024; G01K 7/24; H01S 5/02212; H01S 5/026

(52) U.S. Cl. CPC H01S 5/02407; G01K 7/24; H01S 5/02212; H01S 5/026

(57) ABSTRACT

An optical module includes a temperature controller that performs a function of adjusting the temperature of a semiconductor laser, and an optical monitor that performs a function of monitoring an optical output from the semiconductor laser and monitoring an oscillation wavelength, the optical module includes a heater and a thermistor housed in a package, the heater and the thermistor are electrically connected in parallel, and one end of the heater and one end of the thermistor are connected to a heater-and-thermistor shared lead pin.

### TECHNICAL FIELD

The present disclosure relates to an optical module.

### BACKGROUND ART

In order to increase the capacity of optical communication systems and the like, there is a demand for enhancement of optical communication modules used in the optical communication systems and the like. Some enhanced optical communication modules require many functions such as a temperature monitor or a temperature controller for temperature adjustment, an optical output monitor, and an oscillation wavelength monitor as well as applying a current to a semiconductor laser.

For example, Patent Literature 1 discloses a laser module that houses, in a package,
a laser (LD), a photodetector (PD) that monitors light emitted from a back end surface of the laser, a photodetector (PD) that monitors light emitted from the back end surface of the laser and transmitted through an etalon, a thermistor that detects the temperature of the laser, and a first Peltier element and a second Peltier element each having a current applying element and connected in series or in parallel to a pair of input terminals for an external signal provided in the module.

### CITATION LIST

### Patent Literatures

Patent Literature 1: JP 2003-69130 A

### SUMMARY OF INVENTION

### Technical Problem

In the laser module disclosed in Patent Literature 1, eight terminals for exchanging electrical signals between the inside and the outside of the package are shown in the perspective view more specifically illustrating the main part structure, but the relationship with the components housed inside the package is not illustrated.

In addition to the two input terminals to the first Peltier element and the second Peltier element, at least six terminals including terminals for the laser, two photodetectors, and the thermistor and the ground terminal are required as determined from the schematic diagram illustrating the structure.

On the other hand, it is desired to downsize the optical communication module as well as to enhance the optical communication module by adding further functions.

Downsizing of the optical communication module is also limited by the number of terminals that exchange electrical signals between the inside and the outside of the package.

The present disclosure has been made in view of the above points, and an object of the present disclosure is to downsize an optical module including a semiconductor laser, the optical module including a heater and a thermistor inside a package.

### Solution to Problem

An optical module according to the present disclosure includes a package including a stem and a windowed cap with a cylindrical shape, an open end surface of a side wall portion being fixed in contact with a peripheral end portion of an inner plane of the stem, a semiconductor laser housed in the package, to emit a laser beam from a window of the windowed cap, an optical monitor housed in the package, to receive a laser beam from the semiconductor laser and monitor a laser beam from the semiconductor laser, a temperature controller housed in the package, to execute control to change a temperature applied to the semiconductor laser and the optical monitor when a monitored value from the optical monitor deviates from a set monitored value, and to adjust a temperature of the semiconductor laser and a temperature of the optical monitor, a heater housed in the package, a thermistor housed in the package, the thermistor being electrically connected in parallel with the heater, a laser lead pin electrically insulated from and penetrating the stem, the laser lead pin having an inner lead portion exposed from the inner plane of the stem, the inner lead portion of the laser lead pin being connected to an electrode of the semiconductor laser, a monitor lead pin electrically insulated from and penetrating the stem, the monitor lead pin having an inner lead portion exposed from the inner plane of the stem, the inner lead portion of the monitor lead pin being connected to an output terminal of the optical monitor, a lead pin for a temperature controller electrically insulated from and penetrating the stem, the lead pin for the temperature controller having an inner lead portion exposed from the inner plane of the stem, the inner lead portion of the lead pin for the temperature controller being connected to an electrode of the temperature controller, a heater-and-thermistor shared lead pin electrically insulated from and penetrating the stem, the heater-and-thermistor shared lead pin having an inner lead portion exposed from the inner plane of the stem, the inner lead portion of the heater-and-thermistor shared lead pin being connected to a first end of the heater and a first end of the thermistor, and a ground lead pin electrically connected to the stem.

### Advantageous Effects of Invention

According to the present disclosure, the heater and the thermistor housed in the package are electrically connected in parallel, and the lead pin is shared with the heater and the thermistor, so that downsizing can be achieved.

### BRIEF DESCRIPTION OF DRAWINGS

FIG. 1 is a perspective view illustrating a state where a cap is removed from an optical module according to a first embodiment.

FIG. 2 is a perspective view illustrating the optical module according to the first embodiment.

FIG. 3 is a cross-sectional view taken along line III-III in FIG. 1.

FIG. 4 is a block diagram illustrating an optical monitor in the optical module according to the first embodiment.

FIG. 5 is a schematic perspective view illustrating the optical monitor in the optical module according to the first embodiment.

FIG. 6 is a schematic block diagram illustrating an optical module device according to the first embodiment.

FIG. 7 is a circuit diagram of a heater and a thermistor in the optical module according to the first embodiment, the diagram illustrating the relationship between lead pins.

FIG. 8 is a diagram illustrating the relationship between the temperature of the thermistor and a parallel resistance value of the heater and the thermistor in the optical module according to the first embodiment.

FIG. 9 is a circuit diagram of a heater and a thermistor in an optical module according to a reference example, the diagram illustrating the relationship between lead pins.

FIG. 10 is a diagram illustrating a resistance value for the temperature of the heater in the optical module according to the reference example.

FIG. 11 is a diagram illustrating the relationship between the temperature of the thermistor and the resistance value in the optical module according to the reference example.

FIG. 12 is a circuit diagram of a heater and a thermistor in an optical module according to a second embodiment, the diagram illustrating the relationship between lead pins.

FIG. 13 is a circuit diagram of a heater and a thermistor in a modification of the optical module according to the second embodiment, the diagram illustrating the relationship between lead pins.

### DESCRIPTION OF EMBODIMENTS

### First Embodiment

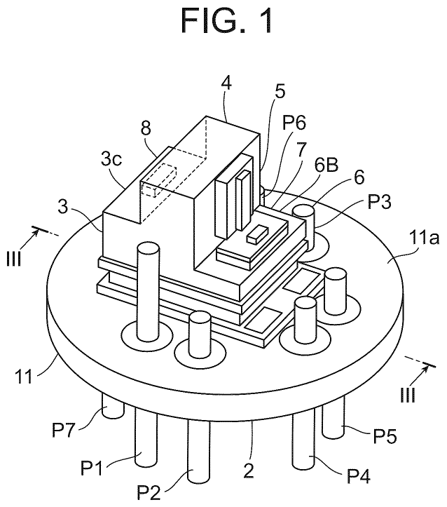

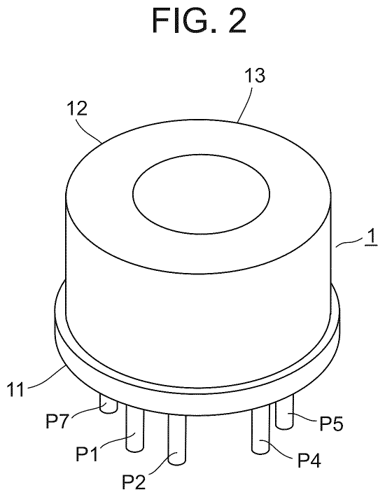

An optical module according to a first embodiment will be described with reference to FIGS. 1 to 8.

The optical module according to the first embodiment is suitable for use as a light source module for digital coherent communication.

The optical module according to the first embodiment is an application example to a TO-CAN optical transmission module for optical communication.

The optical module according to the first embodiment is an optical module including a single-wavelength semiconductor laser.

The optical module according to the first embodiment is an optical module having a function of adjusting the temperature of the semiconductor laser and a function of monitoring an optical output from the semiconductor laser and monitoring an oscillation wavelength.

Therefore, the TO-CAN optical transmission module for optical communication including a single-wavelength semiconductor laser will be described below as an example.

As illustrated in FIGS. 1 to 3, the optical module according to the first embodiment includes a package 1 including a stem 11 and a windowed cap 12 (hereinafter, referred to as cap), a temperature controller 2, a base 3, a semiconductor laser submount (hereinafter, referred to as submount) 4, a semiconductor laser 5, an optical monitor 6, a heater 7, a thermistor 8, a plurality of lead pins P2 to P7, and a ground lead pin P1.

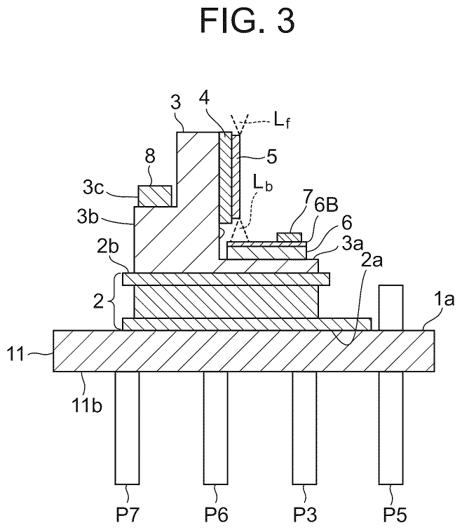

Note that, in FIGS. 1 and 3, wires for electrically connecting the components 2, 5, 6, 7, and 8 and the lead pins P1 to P6 are omitted in order to avoid complexity.

The stem 11 is made of a disk-shaped metal. The shape of the stem 11 is not limited to a disk shape, and may be a columnar shape or a quadrangular prism shape, and is only required to be a flat plate shape having an inner plane 11a and an outer plane 11b parallel to the inner plane 11a.

The inner plane 11a of the stem 11 is a mounting surface and serves as a component mounting region.

In this example, the stem 11 is a disk-shaped metal with a diameter of 5.6 mm.

The cap 12 is a metal lens cap made of a cylindrical metal having an open end, a bottomed portion, and a side wall portion, and with an outer diameter slightly smaller than the diameter of the stem 11.

At the center of the bottomed portion of the cap 12, an opening in which flat glass or a lens as a window 13 is mounted is formed.

The flat glass or lens as the window 13 is attached to the opening formed in the bottomed portion by bonding with an adhesive or through melting in a manner that airtightness is maintained inside and outside the cap.

The end surface of the side wall portion of the cap 12 comes into contact with the peripheral end portion of the inner plane 11a of the stem 11, and is bonded and fixed by electric welding.

The inside surrounded by the stem 11 and the cap 12 is filled with an inert gas or brought into a vacuum state, and is hermetically sealed by shutting off the semiconductor laser 5 from the outside air.

A forward laser beam Lf from the semiconductor laser 5 is emitted through the window 13.

The stem 11 and the cap 12 constitute a TO-CAN package.

The temperature controller 2 is housed in the package and placed on the stem 11.

The temperature controller 2 has a lower surface 2a that is a flat surface and an upper surface 2b that is a flat surface parallel to the lower surface 2a, the lower surface 2a is fixed to the inner plane 11a of the stem 11 with solder or a conductive adhesive, and the upper surface 2b serves as a mounting surface. Hereinafter, the upper surface 2b is referred to as a mounting surface.

The temperature controller 2 heats or cools the mounting surface 2b by current flowing therethrough.

When a monitored value from the optical monitor 6 deviates from a set monitored value, the temperature controller 2 executes control to change the temperature applied to the semiconductor laser 5 and the optical monitor 6.

That is, the temperature controller 2 adjusts the temperature of the semiconductor laser 5 and the temperature of the optical monitor 6.

The temperature controller 2 is a thermo-electric cooler (TEC) including a Peltier element.

The base 3 is an L-shaped metal member that is placed on the mounting surface 2b of the temperature controller 2 and includes a plane portion 3a having flat upper and lower surfaces, and an erected surface portion 3b formed integrally with the plane portion 3a and having a flat erected surface. The base includes a stepped portion having a placement surface 3c that is a horizontal surface on the opposite side of the erected surface of the erected surface portion 3b.

The lower surface of the plane portion 3a of the base 3 is fixed to the mounting surface 2b of the temperature controller 2 with solder or a conductive adhesive.

The semiconductor laser 5 is placed and fixed on the erected surface of the erected surface portion 3b of the base 3 via the semiconductor laser submount 4.

The semiconductor laser 5 is fixed on the erected surface of the erected surface portion 3b of the base 3 in a manner that the optical axis of the forward laser beam Lf and the optical axis of a backward laser beam Lb from the semiconductor laser 5 match the central axis of the stem 11.

The submount 4 is formed of, for example, a substrate made of an aluminum nitride (AlN) dielectric with a metal wiring layer patterned on the surface.

The optical monitor 6 is placed and fixed on the upper surface of the plane portion 3a of the base 3.

The optical monitor 6 is fixed on the upper surface of the plane portion 3a of the base 3 so as to receive the backward laser beam Lb from the semiconductor laser 5.

The optical monitor 6 is disposed at an angle at which the backward laser beam Lb from the semiconductor laser 5 can be received.

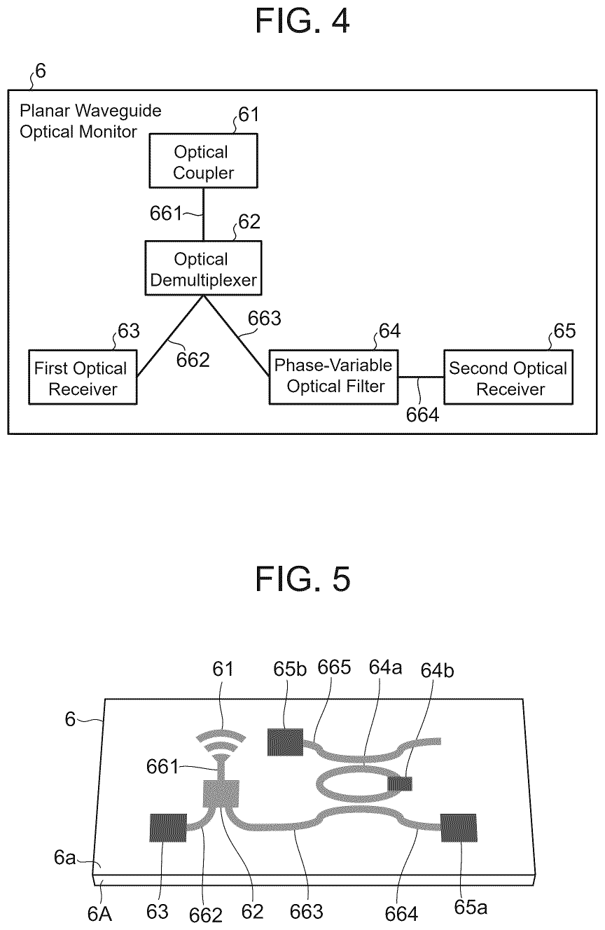

For example, when the angle at which the maximum coupling efficiency of an optical coupler 61 (see FIGS. 4 and 5) in the optical monitor 6 to the backward laser beam Lb from the semiconductor laser 5 can be obtained is 90 degrees with respect to the plane 6a of the optical monitor 6, the optical monitor 6 is disposed at 90 degrees, and when the angle is 80 degrees, the optical monitor 6 is disposed at 80 degrees.

In a case where the angle of the optical monitor 6 with respect to the backward laser beam Lb from the semiconductor laser 5 is set to 90 degrees, the angle formed by the upper surface of the plane portion 3a of the base 3 and the erected surface of the erected surface portion 3b of the base 3 is set to 90 degrees.

In addition, in a case where the angle of the optical monitor 6 with respect to the backward laser beam Lb from the semiconductor laser 5 is set to 80 degrees, the upper surface of the plane portion 3a of the base 3 may be inclined, and the angle formed by the upper surface of the plane portion 3a of the base 3 and the erected surface of the erected surface portion 3b of the base 3 may be set to 80 degrees.

Note that, in the first embodiment, the semiconductor laser 5 is placed and fixed on the erected surface portion 3b of the base 3, and the optical monitor 6 is placed and fixed on the plane portion 3a of the base 3. However, the arrangement relationship may be formed in a manner that the semiconductor laser 5 and the optical monitor 6 are housed inside the package 1, the forward laser beam Lf from the semiconductor laser 5 is emitted to the outside of the package 1, and the backward laser beam Lb from the semiconductor laser 5 is received by the optical monitor 6.

A thermistor 8 is placed and fixed on the placement surface 3c of the stepped portion of the base 3.

By conducting heat on the mounting surface 2b of the temperature controller 2, the base 3 adjusts the temperature of the semiconductor laser 5, that is, heats or cools the semiconductor laser 5 through the submount 4.

At the same time, by conducting heat on the mounting surface 2b of the temperature controller 2, the base 3 adjusts the temperature of the optical monitor 6, that is, heats or cools optical monitor 6.

Since the semiconductor laser 5 and the optical monitor 6, whose temperatures are adjusted by the temperature controller 2, are arranged perpendicularly to each other by the base 3, the area occupied by the semiconductor laser 5 and the optical monitor 6 on the mounting surface 2b of the temperature controller 2 can be reduced. As a result, the temperature controller 2 can be downsized, and the optical module can be downsized accordingly.

In addition, the thermistor 8 is housed in the package 1 and measures the temperature inside the package 1.

The thermistor 8 is housed in the package 1 in order to execute accurate temperature control by the temperature controller 2 and to enhance the functionality of the optical module.

That is, by detecting the temperature of the semiconductor laser 5 and the temperature of the optical monitor 6 by the thermistor 8 in advance preparation for operating the optical module, it is possible to more accurately know the relationship between a target value of a monitored value of the laser beam from the semiconductor laser 5 and the temperature of the semiconductor laser 5 and the temperature of the optical monitor 6.

Furthermore, during the operation of the optical module, the temperature of the semiconductor laser 5 and the temperature of the optical monitor 6 are detected regularly, periodically, or randomly by the thermistor 8, so that the temperature of the semiconductor laser 5 and the temperature of the optical monitor 6 during the operation of the optical module can be known more accurately.

In this example, since the thermistor 8 is placed and fixed on the placement surface 3c of the stepped portion of the base 3, the temperature of the base 3, that is, the temperature of the semiconductor laser 5 and the temperature of the optical monitor 6 can be measured and detected.

Note that the thermistor 8 is placed and fixed on the placement surface 3c of the stepped portion of the base 3, but the thermistor 8 may be placed and fixed on a portion other than the placement surface 3c of the stepped portion of the base 3, the mounting surface 2b of the temperature controller 2, or the inner plane 11a of the stem 11.

In short, it is only required that the thermistor 8 is housed in the package 1, can measure the temperature inside the package 1, and detect the temperature of the semiconductor laser 5 and the temperature of the optical monitor 6 from the measurement result.

The semiconductor laser 5 is a single-wavelength semiconductor laser, that is, a single-mode laser oscillating at a single wavelength. As the single-wavelength semiconductor laser, for example, a distributed feedback (DFB) laser diode element (chip) or a distributed Bragg reflector (DBR) laser diode element (chip) is used.

The semiconductor laser 5 emits the forward laser beam Lf from the emission surface, and the backward laser beam Lb from the back surface. The forward laser beam Lf is used for optical communication, and the backward laser beam Lb is monitored.

In this type of single-wavelength semiconductor laser, the optical intensity changes depending on the supplied drive current, the optical intensity also changes depending on the temperature of the laser itself, and in general, the optical output increases as the temperature decreases.

Furthermore, the oscillation wavelength of a laser beam from the single-wavelength semiconductor laser also changes depending on the temperature of the laser. The oscillation wavelength of the laser beam from the single-wavelength semiconductor laser also changes depending on Joule heat due to the drive current.

Therefore, in the first embodiment, by monitoring the backward laser beam Lb from the semiconductor laser 5 using the optical monitor 6, and adjusting the temperature of the semiconductor laser 5 using the temperature controller 2, the wavelength of the laser beam oscillated from the semiconductor laser 5 is kept constant.

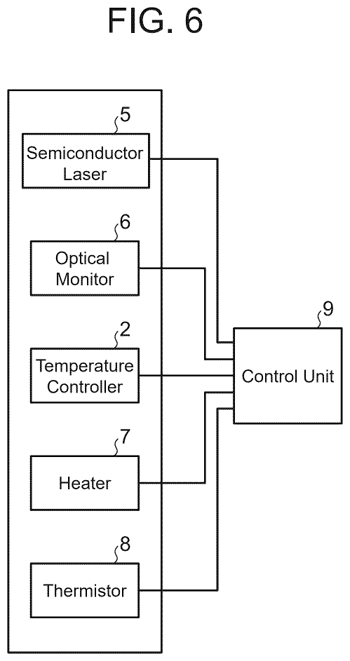

The optical monitor 6 outputs, to a control unit 9 (see FIG. 6) that controls the temperature controller 2, a monitored value for causing the temperature controller 2 to execute control to change the temperature applied to the semiconductor laser 5 and the optical monitor 6.

The control unit 9 controls the temperature controller 2, the semiconductor laser 5, the optical monitor 6, and the heater 7. The control unit 9 exchanges signals with the semiconductor laser 5, the optical monitor 6, and the temperature controller 2, and controls the current and voltage to each of the semiconductor laser 5, the optical monitor 6, and the temperature controller 2, thereby controlling the optical intensity and the wavelength of the laser beam from the semiconductor laser 5.

Temperature information obtained by the thermistor 8 is input to the control unit 9 in advance preparation, and during the operation of the optical module, temperature information obtained by the thermistor 8 regularly, periodically, or randomly is input to the control unit 9.

The optical monitor 6 measures the optical intensity of the backward laser beam Lb from the semiconductor laser 5, obtains an optical power monitored value Ip, which is one of monitored values, including a current value for controlling the value of the drive current to the semiconductor laser 5 in a manner that the optical output of the semiconductor laser 5 reaches a target value, and obtains a wavelength monitored value Iλ, which is one of monitor values, including a current value used for controlling the value of the current to be supplied to the temperature controller 2 in a manner that the wavelength of the laser beam from the semiconductor laser 5 reaches a target value.

The optical monitor 6 constitutes a part of a wavelength locker for wavelength control of the laser beam from the semiconductor laser 5.

Control is executed by the control unit 9, and the control causes the temperature controller 2 to heat the mounting surface 2b depending on the value of the current supplied when the optical power monitored value Ip is larger than a current set value, which is one of the set monitored values, thereby increasing the temperature applied to the semiconductor laser 5 and the optical monitor 6, and to cool the mounting surface 2b depending on the value of the current supplied when the optical power monitored value Ip is smaller than the current set value, thereby reducing the temperature applied to the semiconductor laser 5 and the optical monitor 6.

The current set value is set to, for example, ±10% of a target value Ip_target of the optical power monitored value Ip when the drive current at which the optical output, that is, the optical intensity of the semiconductor laser 5 reaches the target value is supplied to the semiconductor laser 5.

When the wavelength-monitored value Iλ/Ip, which is the ratio between the optical power monitored value Ip and the wavelength monitored value Iλ, deviates from a wavelength set value, which is one of the set monitored values, the temperature controller 2 changes the temperature of the mounting surface 2b depending on the value of the supplied current, thereby changing the temperature applied to the semiconductor laser 5 and the optical monitor 6.

In this example, the control is executed in which the temperature controller 2 heats the mounting surface 2b depending on the value of the current supplied when the wavelength-monitored value Iλ//Ip is larger than the wavelength set value, thereby increasing the temperature applied to the semiconductor laser 5 and the optical monitor 6, and cools the mounting surface 2b depending on the value of the current supplied when the wavelength-monitored value Iλ/Ip is smaller than the wavelength set value, thereby reducing the temperature applied to the semiconductor laser 5 and the optical monitor 6.

For example, the wavelength set value is set to ±10% of a target value Iλ_target of the wavelength-monitored value Iλ/Ip when the wavelength λLD of the laser beam from the semiconductor laser 5 is set to a target value λ_target.

As illustrated in FIGS. 4 and 5, the optical monitor 6 includes the optical coupler 61, an optical demultiplexer 62, a first optical receiver 63, an optical filter 64, a second optical receiver 65, and optical waveguides 661 to 665.

The optical monitor 6 is, for example, a planar waveguide optical monitor using a silicon photonic chip formed by integrating the optical coupler 61, the optical demultiplexer 62, the first optical receiver 63, the optical filter 64, the second optical receiver 65, and the optical waveguides 661 to 665 on a plane of a silicon (Si) substrate 6A.

The optical waveguides 661 to 665 are silicon waveguides made of silicon.

The optical coupler 61 receives the backward laser beam Lb from the semiconductor laser 5 and couples the backward laser beam Lb entering perpendicularly the plane 6a of the optical monitor 6 to the optical waveguide 661.

The optical coupler 61 is, for example, a grating coupler. Since the grating coupler has a function of coupling the backward laser beam Lb from the semiconductor laser 5, the beam coming from above the plane 6a of the optical monitor 6, to the optical waveguide 661, the plane 6a of the optical monitor 6 and the semiconductor laser 5 are arranged by the base 3 at an angle at which the maximum coupling efficiency of the grating coupler can be obtained.

Note that the optical coupler 61 may be an elephant coupler.

Since the grating coupler can increase the optical mode, the grating coupler has a feature that the positional dependence is smaller than in the end face coupling of waveguides. Therefore, the grating coupler is preferable for the optical coupler 61 in this example.

The optical demultiplexer 62 demultiplexes the backward laser beam Lb received by the optical coupler 61 and transmitted from the semiconductor laser 5 via the optical waveguide 661 into two laser beams.

The optical demultiplexer 62 is, for example, any of a directional coupler, a multi-mode interferometer (MMI), or a Y-branch waveguide. In this example, MMI is used as the optical demultiplexer 62.

The optical coupler 61 receives the backward laser beam Lb from the semiconductor laser 5, and the first optical receiver 63 then receives one laser beam demultiplexed by the optical demultiplexer 62 via the optical waveguide 662, photoelectrically converts the received light beam, and outputs the current based on the backward laser beam Lb from the semiconductor laser 5 to the output terminal as a first monitored value.

The first optical receiver 63 directly converts the backward laser beam Lb obtained by the optical coupler 61 coupling the backward laser beam Lb from the semiconductor laser 5 into a current, and thus functions as an optical power monitor of the semiconductor laser 5.

That is, the current value Ip of the current obtained from the first optical receiver 63 is the optical power monitored value Ip indicating the optical output, that is, the optical intensity of the laser beam from the semiconductor laser 5 as the current value, and the first optical receiver 63 outputs the optical power monitored value Ip to the output terminal as the first monitor value.

The first optical receiver 63 is a waveguide optical receiver or a surface-incident optical receiver, and in this example, a photodiode which is a silicon germanium (SiGe) optical receiver is used.

The optical coupler 61 receives the backward laser beam Lb from the semiconductor laser 5, and the optical filter 64 then receives the other laser beam demultiplexed by the optical demultiplexer 62 via the optical waveguide 663.

The optical filter 64 is a phase-variable optical filter with wavelength temperature dependence.

That is, the peak value of the wavelength of the laser beam output from the optical filter 64 has temperature dependence in which the wavelength shifts to a long wavelength side as the temperature of the optical filter 64 increases.

The optical filter 64 is a ring resonator, and in this example, the ring resonator is used as a filter with periodic characteristics.

Note that the optical filter 64 is not limited to the ring resonator filter.

Ideally, a filter without temperature dependence is preferable as the optical filter 64.

Here, in general, the temperature dependence is less likely to be zero, and thus the filter may be a filter with temperature dependence in which the wavelength shifts to a long wavelength side as the temperature increases, or a filter with temperature dependence in which the wavelength shifts to a short wavelength side as the temperature increases.

Instead of the ring resonator filter, a Mach-Zehnder interferometer (MZ interferometer) or a distributed Bragg reflector (DBR) filter may be used.

In this example, a ring resonator 64a is used as the optical filter 64, and hereinafter, the ring resonator 64a is referred to as a ring resonator filter.

The ring resonator filter 64a includes a closed-loop optical waveguide.

The optical waveguide 663 connected to the other output terminal of the optical demultiplexer 62 is set as an input side, the optical waveguide 664 connected to the input terminal of the second optical receiver 65 is set as an output side, and the optical waveguide forming a closed loop constituting the ring resonator filter 64a, and the optical waveguide 663 on the input side and the optical waveguide 664 on the output side that is continuous with the optical waveguide 663 are coupled to generate resonance in the optical waveguide forming a closed loop, so that the function of the filter is performed.

Note that the ring resonator filter is also coupled to the optical waveguide 665 on the other output side that is disposed to face the optical waveguide 664 on the output side with respect to the ring resonator filter 64a.

The optical waveguide forming a closed loop constituting the ring resonator filter 64a is a silicon waveguide made of silicon.

The optical waveguide forming a closed loop has a diameter of about 100 μm, is very small, can be downsized, and can suppress the influence of the temperature gradient due to the environmental temperature of the ring resonator filter 64a.

As the second optical receiver 65, one of a photodiode 65a that is connected to, that is, coupled to the ring resonator filter 64a via the optical waveguide 664 on the output side and receives the transmitted light from the ring resonator filter 64a, and a photodiode 65b that is connected to, that is, coupled to the ring resonator filter 64a via the optical waveguide 665 on the other output side disposed to face the optical waveguide 664 and receives the transmitted light from the ring resonator filter 64a is used.

As is generally known, since the optical waveguide 664 on the output side and the optical waveguide 665 on the other output side are arranged to face each other with respect to the ring resonator filter 64a, the intensity of the current flowing through the photodiode 65a connected to the through port of the optical waveguide 664 on the output side with respect to the phase is inverted with respect to the intensity of the current flowing through the photodiode 65b connected to the drop port of the optical waveguide 665 on the other output side with respect to the phase.

That is, the intensity of the current flowing through each of the photodiode 65a and the photodiode 65b with respect to the phase is inverted from 1 to 0 and from 0 to 1 every 2 m, and when the intensity of the current flowing through one photodiode 65a with respect to the phase indicates 1, the intensity of the current flowing through the other photodiode 65b with respect to the phase indicates 0. Conversely, when the intensity of the current flowing through one photodiode 65a with respect to the phase indicates 0, the intensity of the current flowing through the other photodiode 65b with respect to the phase indicates 1.

In short, the slope of the intensity of the current flowing through the photodiode 65a is similar to the slope of the intensity of the current flowing through the photodiode 65b.

Therefore, either the photodiode 65a or the photodiode 65b may be used as the second optical receiver 65.

With regard to the output from the second optical receiver 65, the optical coupler 61 receives, that is, couples the backward laser beam Lb from the semiconductor laser 5, and the laser beam obtained by filtering the other laser beam demultiplexed by the optical demultiplexer 62 by the ring resonator filter 64a, which is the phase variable optical filter 64, that is, in this example, the laser beam resonated with the backward laser beam Lb is converted into a current. Therefore, when the wavelength of the backward laser beam Lb changes, the current value from the second optical receiver 65 also changes based on the wavelength dependence of the ring resonator filter 64a.

As a result, the current value Iλ of the current obtained from the second optical receiver 65 can be used as the wavelength monitored value Iλ used to obtain the wavelength-monitored value Iλ/Ip of the semiconductor laser 5, and the ring resonator filter 64a and the second optical receiver 65 function as the wavelength monitor of the semiconductor laser 5.

The current value Iλ of the current obtained from the second optical receiver 65 is the wavelength monitored value Iλ, and the second optical receiver 65 outputs the optical power monitored value Ip as a second monitored value to the output terminal.

The wavelength monitored value Iλ, that is, the current value In obtained from the second optical receiver 65 changes depending on not only the wavelength of the backward laser beam Lb from the semiconductor laser 5 but also the optical intensity of the backward laser beam Lb.

Therefore, by dividing the wavelength monitored value Iλ by the optical power monitored value Ip, the wavelength-monitored value Iλ/Ip based only on the wavelength of the backward laser beam Lb is obtained.

Since the temperature of the semiconductor laser 5 and the temperature of the optical monitor 6 are adjusted by the heat on the mounting surface 2b of the temperature controller 2 via the base 3, the increase in the temperature rise of the semiconductor laser 5 and the increase in the temperature of the optical monitor 6 are the same.

When the temperature of the optical monitor 6 changes, the wavelength-monitored value Iλ/Ip shows straightforward wavelength dependence.

In this example, by increasing the temperature with respect to the wavelength of the laser beam from the semiconductor laser 5, the wavelength-monitored value Iλ/Ip has a downward slope.

By adjusting the temperature of the semiconductor laser 5, the wavelength of the laser beam from the semiconductor laser 5 can be adjusted, and precise control can be executed for a single wavelength of the laser beam from the semiconductor laser 5.

In this example, in the optical filter 64, a phase modulator 64b is further disposed on the optical waveguide forming a closed loop constituting the ring resonator filter 64a. In this example, the phase modulator 64b is the heater 7.

The position of a peak wavelength λfilt in the ring resonator filter 64a, that is, the position of the peak of the current value IN obtained from the second optical receiver 65 generally has an individual difference due to a manufacturing error of the ring resonator filter 64a.

The phase modulator 64b controls the ring resonator filter 64a, that is, the phase modulator 64b causes the ring resonator filter 64a to adjust the position of the peak wavelength λfilt.

The current to be supplied to the heater 7 as the phase modulator 64b is a target value Ih_target of the current to be supplied to the heater 7 from which the peak wavelength λfilt of the ring resonator filter 64a is obtained when the optical output in which the wavelength λLD reaches the target value λ_target and the optical intensity reaches the target value Ip_target of the optical power monitored value Ip, acquired in advance preparation for operating the optical module, is obtained from the semiconductor laser 5.

That is, in order to obtain the current value Iλ obtained from the second optical receiver 65 for obtaining the target value Iλ_target of the wavelength-monitored value Iλ/Ip for the target value λ_target of the wavelength ALD of the laser beam from the semiconductor laser 5, the position of the peak wavelength λfilt in the ring resonator filter 64a is adjusted by the phase modulator 64b.

For example, when the target value Iλ_target is at the position of the wavelength-monitored value Iλ/Ip=0, even if the wavelength λLD of the laser beam from the semiconductor laser 5 changes, the value of the wavelength-monitored value Iλ/Ip hardly changes, and the control of the ring resonator filter 64a cannot be executed well.

In order to avoid this, the heater 7 as the phase modulator 64b heats the ring resonator filter 64a to adjust the temperature of the ring resonator filter 64a in a manner that the target value Iλ_target reaches the value of the wavelength-monitored value Iλ/Ip suitable for control.

The target value Iλ_target suitable for controlling the ring resonator filter 64a is determined by adjusting the temperature of the ring resonator filter 64a using the phase modulator 64b in a manner that the target value Iλ_target becomes the wavelength-monitored value Iλ/Ip near the median value in the region where the slope of the wavelength dependence with respect to the change in the temperature of the optical monitor 6, in other words, the change in the temperature of the ring resonator filter 64a is large.

Note that instead of the planar waveguide optical monitor using a silicon photonic chip, the optical monitor 6 may be a planar waveguide optical monitor formed by integrating the optical coupler 61, the optical demultiplexer 62, the first optical receiver 63, the optical filter 64, the second optical receiver 65, and the optical waveguides 661 to 665 on a plane of an indium phosphide (InP) substrate 6A, which is a compound semiconductor.

Furthermore, the optical monitor 6 may be a planar waveguide optical monitor formed by integrating the optical coupler 61, the optical demultiplexer 62, the first optical receiver 63, the optical filter 64, the second optical receiver 65, and the optical waveguides 661 to 665 on a plane of a glass substrate 6A.

The optical coupler 61, the optical demultiplexer 62, the first optical receiver 63, the optical filter 64, the second optical receiver 65, and the optical waveguides 661 to 665 are not necessarily integrated, and the individual components may be modularized.

The first optical receiver 63 and the second optical receiver 65 may be InP optical receivers.

The heater 7 as the phase modulator 64b is disposed on the upper surface of the optical monitor 6 via a heat insulating layer 6B.

In this example, the heat insulating layer 6B is a silicon oxide (SiO₂) layer formed on the substrate 6A of the optical monitor 6 so as to cover the optical coupler 61, the optical demultiplexer 62, the first optical receiver 63, the optical filter 64, the second optical receiver 65, and the optical waveguides 661 to 665.

Note that, in a case where the optical monitor 6 has sufficient heat insulating properties, the amount of heat generated by the heater 7 is small, and the influence on the thermistor 8 is small, the heat insulating layer 6B may be omitted.

Although the heater 7 is disposed on the upper surface of the optical monitor 6, the heater 7 may be disposed on the base 3, the mounting surface 2b of the temperature controller 2, or the inner plane 11a of the stem 11.

In short, in this example, the heater 7 is only required to be housed in the package 1, heat the inside of the package 1, have a small influence on the thermistor 8, and directly or indirectly adjust the temperature of the ring resonator filter 64a in the optical monitor 6.

The temperature controller 2, the semiconductor laser 5, the optical monitor 6, and the heater 7 are controlled by the control unit 9, as illustrated in FIG. 6.

The control unit 9 receives temperature information from the thermistor 8, that is, detection information of the temperature of the semiconductor laser 5 and the temperature of the optical monitor 6 in advance preparation for operating the optical module, and receives detection information of the temperature of the semiconductor laser 5 and the temperature of the optical monitor 6 regularly, periodically, or randomly during the operation of the optical module.

For the semiconductor laser 5, the control unit 9 receives the optical power monitored value Ip from the first optical receiver 63 of the optical monitor 6, and controls the drive current to the semiconductor laser 5 in a manner that the optical power monitored value Ip falls within a range of ±10% of the target value Ip_target of the optical power monitored value that is a current set value.

For the temperature controller 2, the control unit 9 controls the current to be supplied to the temperature controller 2 in a manner that the optical power monitored value Ip from the first optical receiver 63 of the optical monitor 6 falls within a range of the current set value of ±10% of the target value Ip_target of the optical power monitored value.

The control unit 9 supplies a current for heating the mounting surface 2b of the temperature controller 2 to the temperature controller 2 when the optical power monitored value Ip is larger than the current set value, and supplies a current for cooling the mounting surface 2b of the temperature controller 2 to the temperature controller 2 when the optical power monitored value Ip is smaller than the current set value.

As a result, the control is executed in which the temperature controller 2 increases the temperature applied to the semiconductor laser 5 and the optical monitor 6 when the optical power monitored value Ip indicated by the current obtained from the first optical receiver 63 is larger than the current set value, and reduces the temperature applied to the semiconductor laser 5 and the optical monitor 6 when the optical power monitored value Ip is smaller than the current set value.

In addition, the control unit 9 receives the optical power monitored value Ip from the first optical receiver 63 of the optical monitor 6 and the wavelength monitored value Iλ from the second optical receiver 65 of the optical monitor 6, calculates the wavelength-monitored value Iλ/Ip from the received optical power monitored value Ip and the received wavelength monitored value Iλ, and controls the current to be supplied to the temperature controller 2 in a manner that the wavelength-monitored value Iλ/Ip falls within a range of the wavelength set value of ±10% of the target value Iλ_target of the wavelength-monitored value Iλ/Ip when the wavelength λLD of the laser beam from the semiconductor laser 5 is set to the target value λ_target.

When the wavelength-monitored value Iλ/Ip deviates from the wavelength set value, the control unit 9 supplies a current for changing the temperature of the mounting surface 2b to the temperature controller 2.

In this example, the control unit 9 supplies a current for heating the mounting surface 2b of the temperature controller 2 to the temperature controller 2 when the wavelength-monitored value Iλ/Ip is larger than the wavelength set value, and supplies a current for cooling the mounting surface 2b of the temperature controller 2 to the temperature controller 2 when the wavelength-monitored value Iλ/Ip is smaller than the wavelength set value.

As a result, the control is executed in which the temperature controller 2 increases the temperature applied to the semiconductor laser 5 and the optical monitor 6 when the wavelength-monitored value Iλ/Ip from the optical power monitored value Ip indicated by the current obtained from the first optical receiver 63 and the wavelength monitored value Iλ indicated by the current obtained from the second optical receiver 65 is larger than the wavelength set value, and reduces the temperature applied to the semiconductor laser 5 and the optical monitor 6 when the wavelength-monitored value Iλ/Ip is smaller than the wavelength set value.

In addition, control is performed such that, when the wavelength-monitored value Iλ/Ip exceeds the wavelength set value, the temperature controller 2 increases the temperature applied to the semiconductor laser 5 and the optical monitor 6, and when the optical power monitored value Ip becomes smaller than the current set value as a result, increases the drive current supplied to the semiconductor laser 5, and control is performed such that, when the wavelength-monitored value Iλ/Ip is smaller than the wavelength set value, the temperature controller 2 decreases the temperature applied to the semiconductor laser 5 and the optical monitor 6, and when the optical power monitored value Ip is larger than the current set value as a result, decreases the drive current supplied to the semiconductor laser 5.

The control unit 9 supplies, to the heater 7 serving as the phase modulator 64b for the optical filter 64, a current with the target value Ih_target at the time of obtaining the optical output of the laser beam in which the optical intensity of the laser beam from the semiconductor laser 5 reaches the target value and the wavelength λLD of the laser beam from the semiconductor laser 5 reaches the target value λ_target.

As a result, under the control of the control unit 9, the heater 7 heats the optical monitor 6, specifically, heats the ring resonator filter 64a, thereby adjusting the temperature of the ring resonator filter 64a.

The control unit 9 and the optical monitor 6 constitute the wavelength locker for wavelength control of the laser beam from the semiconductor laser 5.

The optical module and the control unit 9 constitute the optical module device.

The semiconductor laser 5, the optical monitor 6, the temperature controller 2, the heater 7, and the thermistor 8 are electrically connected to the lead pins P1 to P6 by wire bonding using wires (not illustrated) such as gold wires in order to exchange signals with the control unit 9.

Each of the lead pins P1 to P6 penetrates through a corresponding through-hole formed at a set position on the stem 11, and is fixed to the stem 11 by sealing glass filled and solidified between the lead pins P1 to P6 and the corresponding through-holes. The sealing glass electrically insulates each of the lead pins P1 to P6 from the stem 11 and maintains airtightness.

One end surface of the ground lead pin P7 is in contact with the outer plane 11b of the stem 11 and bonded thereto by electric welding or brazing, so that the ground lead pin P7 is fixed to the stem 11.

The ground lead pin P7 is electrically grounded, and the stem 11 is set to the ground potential by the ground lead pin P7. That is, the stem 11 also serves as a ground node.

The optical module according to the first embodiment requires a total of seven lead pins including six lead pins P1 to P6 for the individual components and one ground lead pin P7, and the optical module can be configured with a small number of lead pins.

As a result, a standard CAN package with a diameter of 5.6 mm, in which the number of lead pins is seven at a maximum, can be used, and downsizing can be achieved.

The connection of the inner lead portions of the lead pins P1 to P6 exposed from the inner plane 11a of the stem 11 is, for example, as follows. Here, the relationship between the lead pins P1 to P6 and the individual components is merely an example, and is not limited thereto.

The lead pin P1 is connected to one electrode of the semiconductor laser 5, and transmits a drive current from the control unit 9 to the semiconductor laser 5. The lead pin P1 is a laser lead pin for the semiconductor laser 5.

The lead pin P2 and the lead pin P3 are connected to a pair of electrodes in the temperature controller 2, that is, the positive electrode and the negative electrode, respectively, and transmit the current supplied from the control unit 9 to the temperature controller 2. The lead pin P2 and the lead pin P3 are temperature-controller lead pins for the temperature controller 2.

Each of the lead pin P4 and the lead pin P5 is connected to the output terminals of the optical monitor 6, and transmit a monitored value from the optical monitor 6 to the control unit 9. The lead pin P4 and the lead pin P5 are monitor lead pins for the optical monitor 6.

The lead pin P4 is connected to the output terminal of the first optical receiver 63 of the optical monitor 6, and transmits a current indicating the optical power monitored value Ip from the first optical receiver 63 to the control unit 9.

The lead pin P5 is connected to the output terminal of the second optical receiver 65 of the optical monitor 6, and transmits a current indicating the wavelength monitored value Iλ from the second optical receiver 65 to the control unit 9.

The lead pin P6 is a heater-and-thermistor shared lead pin to which one end of the heater 7 and one end of the thermistor 8 are connected.

The other end of the heater 7 and the other end of the thermistor 8 are electrically connected to the inner plane 11a of the stem 11, which is at the ground potential (ground node), by wire bonding using wires (not illustrated) such as gold wires, and are connected to the ground lead pin P7.

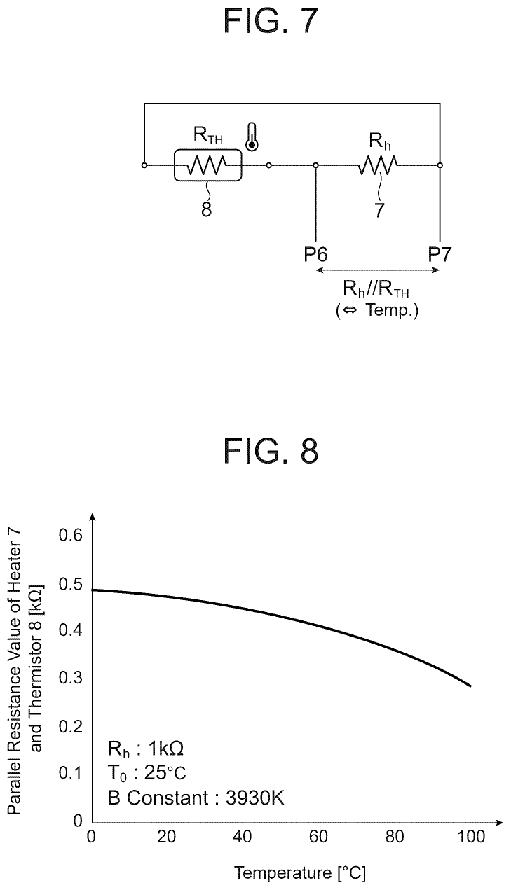

That is, as illustrated in FIG. 7, the heater 7 and the thermistor 8 are connected in parallel between the heater-and-thermistor shared lead pin P6 and the ground lead pin P7.

One heater-and-thermistor shared lead pin P6 suffices for two components, or the thermistor 8 and the heater 7 except for the ground lead pin P7, and one lead pin is reduced.

Next, the relationship between the thermistor 8 and the heater 7, and the lead pins associated therewith, that is, the heater-and-thermistor shared lead pin P6, which is a feature of the optical module according to the first embodiment, will be described.

As described above, the heater 7 functions as the phase modulator 64b for the ring resonator filter 64a in the optical filter 64, and heats the ring resonator filter 64a to adjust the temperature of the ring resonator filter 64a.

The heater 7 has low power and a high resistance value Rₕ.

As described above, the thermistor 8 measures the temperature inside the package 1, particularly measures and detects the temperature of the semiconductor laser 5 and the temperature of the optical monitor 6 in order to execute accurate temperature control by the temperature controller 2.

Therefore, it is necessary that the heater 7 and the thermistor 8 are independently controlled, and the influence of heating by the heater 7 on the thermistor 8 is small, and this point will be described.

In the optical module according to the first embodiment, the heater 7 and the thermistor 8 are electrically connected in parallel between the heater-and-thermistor shared lead pin P6 and the ground lead pin P7 (ground node), and the heater 7 and the thermistor 8 described below as a reference example are used.

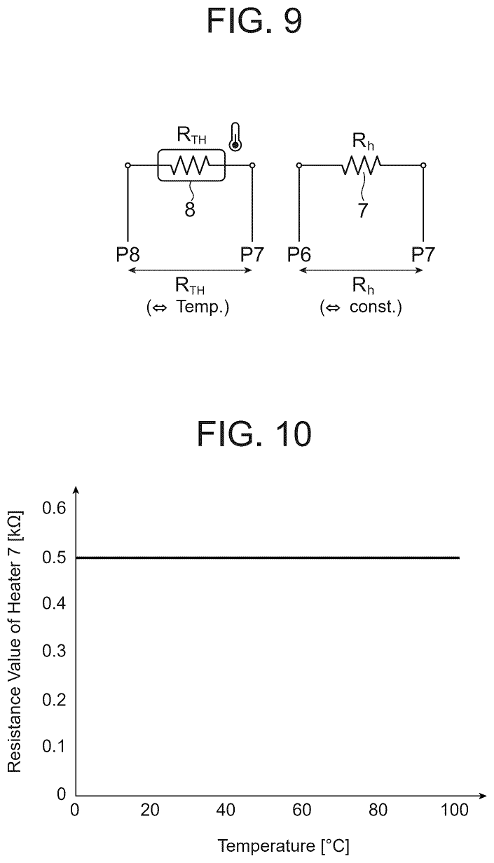

The heater 7 has characteristics as a resistor in this example, and as illustrated in FIG. 9 as the reference example, shares the ground lead pin P7 with the thermistor 8, but the resistance value Rₕ in a case where a lead pin connected to one end is different from that of the thermistor 8 indicates a constant value of 0.5 kΩ in the range of the temperature from 0 degrees to 100 degrees as illustrated in FIG. 10.

That is, in this example, the heater 7 is a heater with a resistance value Rₕ independent of temperature of 0.5 kΩ in the operating temperature range of the optical module, and has low power and high resistance.

In FIG. 10, the horizontal axis represents the operating temperature of the optical module, in this example, the temperature corresponding to the temperature of the semiconductor laser 5 and the temperature of the optical monitor 6, and the vertical axis represents the resistance value Rₕ of the heater 7.

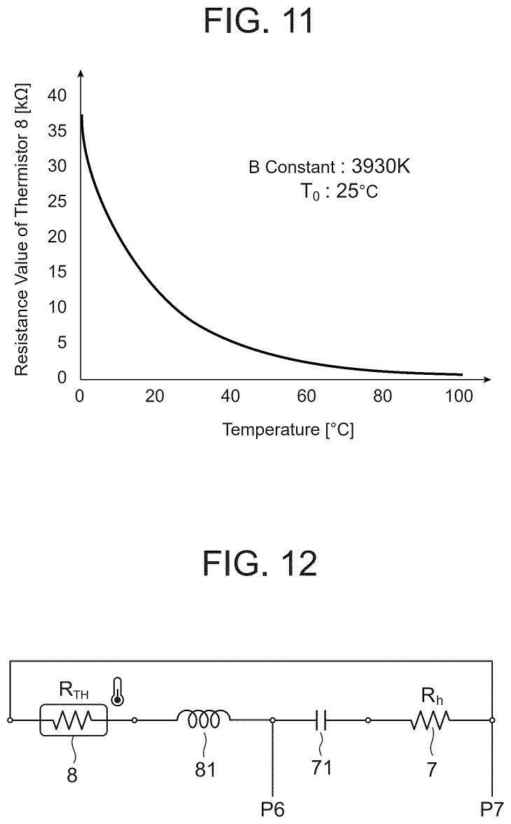

In this example, the thermistor 8 has characteristics as a resistor whose resistance value R_{TH} changes depending on the temperature, and as illustrated in FIG. 9 as the reference example, the resistance value R_{TH} in a case where a lead pin connected to one end is different from that of the heater 7 decreases as the temperature of the thermistor 8 increases, as illustrated in FIG. 11, and indicates 35 kΩ at 0 degrees, 10 kΩ at 25 degrees, 4.16 kΩ at 50 degrees, and 0.7 kΩ at 100 degrees.

In FIG. 11, the horizontal axis represents the temperature of the semiconductor laser 5 and the temperature of the optical monitor 6, and the vertical axis represents the resistance value R_{TH} of the thermistor 8.

In this example, a thermistor with characteristics of R0: 10 kΩ, T0: 25 degrees, and B constant: 3930 K is used as the thermistor 8.

In addition, the curve of the resistance value for the temperature of the thermistor 8 illustrated in FIG. 9 is a result obtained for a thermistor in which the resistance value R0 is 10 kΩ and the B constant is 3930 K when the temperature T0 is 25 degrees using a generally known method of calculating the resistance value R_{TH} at the temperature T of the thermistor.

That is, in the operating temperature range of the optical module according to the first embodiment, the resistance value R_{TH} of the thermistor 8 is designed to be larger than the resistance value Rₕ of the heater 7, and the resistance value R_{TH} of the thermistor 8 and the resistance value Rₕ of the heater 7 are designed to be close to each other.

Specifically, the resistance value Rₕ of the heater 7 indicates a constant value without depending on the temperature, the resistance value R_{TH} of the thermistor 8 changes depending on the temperature, and the relationship between the resistance value R_{TH} of the thermistor 8 and the resistance value Rₕ of the heater 7 is set in a manner that the resistance value R_{TH} of the thermistor 8 is larger than the resistance value Rₕ of the heater 7 and is equal to or less than 70 times the resistance value Rₕ of the heater 7 in the operating temperature range of the semiconductor laser 5 and the optical monitor 6.

In the optical module according to the first embodiment, the heater 7 and the thermistor 8 are electrically connected in parallel between the heater-and-thermistor shared lead pin P6 and the ground lead pin P7, and a DC voltage is applied between the heater-and-thermistor shared lead pin P6 and the ground lead pin P7 and a DC current is caused to flow through the heater 7 and the thermistor 8. In this example, the resistance value R_{TH} changes depending on the temperature in the thermistor 8, and thus by measuring the voltage between the heater-and-thermistor shared lead pin P6 and the ground lead pin P7 and reading the change in the resistance value R_{TH}, the thermistor 8 can measure and detect the temperature inside the package 1, that is, the temperature of the semiconductor laser 5 and the temperature of the optical monitor 6.

That is, as illustrated in FIG. 8, the parallel resistance value Rₕ//R_{TH} of the heater 7 and the thermistor 8 between the heater-and-thermistor shared lead pin P6 and the ground lead pin P7 decreases as the temperature of the thermistor 8 increases. At 25 degrees, the resistance value R_{TH} of the thermistor 8 is 10 kΩ and the resistance value Rₕ of the heater 7 is 0.5 kΩ, and thus the parallel resistance value indicates 0.48 kΩ. At 100 degrees, the resistance value R_{TH} of the thermistor 8 is 0.7 kΩ and the resistance value Rₕ of the heater 7 is 0.5 kΩ, and thus the parallel resistance value indicates 0.29 kΩ.

In FIG. 8, the horizontal axis represents the temperature of the thermistor 8, that is, the temperature of the semiconductor laser 5 and the temperature of the optical monitor 6, and the vertical axis represents the parallel resistance value Rₕ//R_{TH} of the resistance value Rₕ of the heater 7 and the resistance value R_{TH} of the thermistor 8.

Since the resistance value Rₕ of the heater 7 is constant regardless of the temperature change and the resistance value R_{TH} of the thermistor 8 largely changes depending on the temperature, as is clear from FIG. 8, the relationship between the parallel resistance value Rₕ//R_{TH} of the heater 7 and the thermistor 8 and the temperature of the thermistor 8, that is, the relationship between the temperature of the semiconductor laser 5 and the temperature of the optical monitor 6 is determined on a one-to-one basis, the parallel resistance value Rₕ//R_{TH} changes depending on the temperature change, and the resistance value R_{TH} of the thermistor 8 can be read based on the change in the temperature of the semiconductor laser 5 and the temperature of the optical monitor 6.

In order to read the resistance value R_{TH} of the thermistor 8, in this example, in the operating temperature range of the semiconductor laser 5 and the optical monitor 6, it is set that the resistance value R_{TH} of the thermistor 8 is larger than the resistance value Rₕ of the heater 7, and the parallel resistance value Rₕ//R_{TH} of the heater 7 and the thermistor 8 changes by 0.1% or more per degree of temperature change with respect to the maximum value of the parallel resistance value Rₕ//R_{TH} in the operating temperature range.

That is, the resistance value R_{TH} of the thermistor 8 and the resistance value Rₕ of the heater 7 are designed to be close to each other so as to satisfy the condition that the parallel resistance value Rₕ//R_{TH} of the heater 7 and the thermistor 8 changes by 0.1% or more per degree of temperature change with respect to the maximum value of the parallel resistance value Rₕ/R_{TH} in the operating temperature range.

As a result, the measurement accuracy of the resistance value R_{TH} of the thermistor 8 is improved.

Therefore, the parallel resistance value Rₕ/R_{TH} between the heater-and-thermistor shared lead pin P6 and the ground lead pin P7, the control unit 9 causes a direct current to flow between the heater-and-thermistor shared lead pin P6 and the ground lead pin P7, and measures the voltage between the heater-and-thermistor shared lead pin P6 and the ground lead pin P7 based on the direct current flowing between the heater-and-thermistor shared lead pin P6 and the ground lead pin P7, so that the temperature of the semiconductor laser 5 and the temperature of the optical monitor 6 can be obtained.

Note that the control unit 9 converts an analog voltage between the heater-and-thermistor shared lead pin P6 and the ground lead pin P7 into a digital signal by an analog-digital converter (ADC), and uses the digital signal under control.

In addition, when the temperature of the semiconductor laser 5 and the temperature of the optical monitor 6 are detected by the thermistor 8, a direct current also flows through the heater 7, but the heater 7 is a low-power heater used for adjusting the temperature of the ring resonator filter 64a in the optical filter 64, and thus the heater 7 does not adversely affect the temperature of the semiconductor laser 5 and the temperature of the optical monitor 6.

In the detection of the temperature of the semiconductor laser 5 and the temperature of the optical monitor 6 by the thermistor 8 in advance preparation for operating the optical module, a direct current does not flow through the heater 7 for a long time, and from this point as well, the heater 7 does not adversely affect the temperature of the semiconductor laser 5 and the temperature of the optical monitor 6.

In addition, also during the operation of the optical module, the temperature of the semiconductor laser 5 and the temperature of the optical monitor 6 are detected by the thermistor 8. However, the detection is performed regularly, periodically, or randomly, but performed in a short time. Therefore, heating of the heater 7 does not adversely affect the temperature of the semiconductor laser 5 and the temperature of the optical monitor 6.

On the other hand, in adjusting the temperature of the ring resonator filter 64a during the operation of the optical module, when the control unit 9 supplies a direct current between the heater-and-thermistor shared lead pin P6 and the ground lead pin P7, more current flows through the heater 7 than through the thermistor 8 because the resistance value Rₕ of the heater 7 is set to be smaller than the resistance value R_{TH} of the thermistor 8. Therefore, it is possible to easily supply the current with the target value Ih_target to the heater 7, and the temperature of the ring resonator filter 64a can be easily adjusted.

In short, in the optical module according to the first embodiment, the heater 7 and the thermistor 8 are electrically connected in parallel between the heater-and-thermistor shared lead pin P6 and the ground lead pin P7, in the relationship between the resistance value Rₕ of the heater 7 and the resistance value R_{TH} of the thermistor 8, the resistance value Rₕ of the heater 7 is large to such an extent that the change in the resistance value R_{TH} of the thermistor 8 can be read, and in adjusting the temperature of the ring resonator filter 64a during the operation of the optical module, the resistance value Rₕ of the heater 7 is small so that more current flows through the heater 7 than through the thermistor 8, and thus the heater 7 and the thermistor 8 share the heater-and-thermistor shared lead pin P6 and the ground lead pin P7, but functions equivalent to those in a heater and a thermistor in which different lead pins are connected to one ends can be obtained.

Meanwhile, in this example, the heater having the resistance value Rₕ that does not depend on the temperature in the operating temperature range of the optical module is used as the heater 7, but a heater having a characteristic that the resistance value Rₕ changes slightly depending on the temperature may be used as the heater 7.

In the case of using the heater having a characteristic that the resistance value Rₕ changes slightly depending on the temperature, the control unit 9 may correct a change of the resistance value Rₕ of the heater 7 for the temperature in the parallel resistance value Rₕ//R_{TH} read by the control unit 9, and obtain the temperature of the semiconductor laser 5 and the temperature of the optical monitor 6.

Alternatively, the relationship between the temperature and the parallel resistance value Rₕ//R_{TH} may be examined in advance to obtain the characteristic diagram illustrated in FIG. 8, the control unit 9 may store the relationship between the temperature and the parallel resistance value Rₕ//R_{TH} illustrated in the characteristic diagram as a table, and the parallel resistance value Rₕ//R_{TH} read by the control unit 9 may be compared with the relationship stored in the table to obtain the temperature of the semiconductor laser 5 and the temperature of the optical monitor 6.

As described above, the optical module according to the first embodiment includes the temperature controller 2 that performs a function of adjusting the temperature of the semiconductor laser 5 and the optical monitor 6 that performs a function of monitoring the optical output from the semiconductor laser 5 and monitoring the oscillation wavelength, and further includes the heater 7 and the thermistor 8. The heater 7 and the thermistor 8 are electrically connected in parallel, and one end of the heater 7 and one end of the thermistor 8 are connected to the heater-and-thermistor shared lead pin P6. As a result, the heater 7 and the thermistor 8 are substantially independently controlled, and one heater-and-thermistor shared lead pin P6 suffices as the lead pin for the heater 7 and the thermistor 8 except for the ground lead pin P7, and the optical module with enhanced functions can be downsized.

In short, in the optical module according to the first embodiment, heating by the heater 7 and temperature measurement and detection by the thermistor 8 can be performed independently by using one heater-and-thermistor shared lead pin P6 for the heater 7 and the thermistor 8, and the function of the optical module can be improved while the optical module is downsized.

In the first embodiment, the heater 7 is used to adjust the temperature of the ring resonator filter 64a in the optical monitor 6, but may be used to adjust the temperature of other components or adjust the temperature environment inside the package.

Furthermore, in the first embodiment, the thermistor 8 is used to measure and detect the temperature of the semiconductor laser 5 and the temperature of the optical monitor 6 in advance preparation for operating the optical module and during the operation of the optical module. However, the thermistor 8 may be used to measure and detect other components or to measure and detect the temperature environment inside the package.

### Second Embodiment

An optical module according to a second embodiment will be described with reference to FIG. 12.

The optical module according to the second embodiment is different from the optical module according to the first embodiment in that a capacitor 71 electrically connected in series with the heater 7 between the heater-and-thermistor shared lead pin P6 and the ground node and an inductor 81 electrically connected in series with the thermistor 8 between the heater-and-thermistor shared lead pin P6 and the ground node are housed in the package 1, and other points are the same or similar.

Note that in FIG. 12, the same reference numerals as those in FIG. 7 denote the same or corresponding parts.

Hereinafter, differences from the optical module according to the first embodiment will be mainly described.

The capacitor 71 is electrically connected in series between the heater 7 and the heater-and-thermistor shared lead pin P6.

The inductor 81 is electrically connected in series between the thermistor 8 and the heater-and-thermistor shared lead pin P6.

The series body of the heater 7 and the capacitor 71 and the series body of the thermistor 8 and the inductor 81 are electrically connected in parallel between the heater-and-thermistor shared lead pin P6.

During the operation of the optical module, when the control unit 9 supplies an alternating current between the heater-and-thermistor shared lead pin P6 and the ground lead pin P7 in a manner that an alternating current that is a current with the target value Ih_target flows to the heater 7, the temperature of the ring resonator filter 64a is adjusted to a temperature at which the peak wavelength λfilt of the ring resonator filter 64a is obtained.

Since an alternating current is supplied between the heater-and-thermistor shared lead pin P6 and the ground lead pin P7, no current flows through the series body of the thermistor 8 and the inductor 81.

In short, AC power can be applied only to the series body of the heater 7 and the capacitor 71.

On the other hand, in advance preparation for operating the optical module in order to more accurately know the relationship between the target value of the monitored value of the laser beam from the semiconductor laser 5 and the temperature of the semiconductor laser 5 and the temperature of the optical monitor 6, when the control unit 9 supplies a direct current between the heater-and-thermistor shared lead pin P6 and the ground lead pin P7, the control unit 9 can obtain the resistance value between the heater-and-thermistor shared lead pin P6 and the ground lead pin P7 by measuring a DC voltage on the basis of the direct current flowing between the heater-and-thermistor shared lead pin P6 and the ground lead pin P7, and can obtain the temperature of the semiconductor laser 5 and the temperature of the optical monitor 6 from the relationship of the characteristic diagram illustrated in FIG. 11 in consideration of the resistance value of the inductor 81.

Since a direct current is supplied between the heater-and-thermistor shared lead pin P6 and the ground lead pin P7, no current flows through the series body of the heater 7 and the capacitor 71.

Note that since the resistance value of the inductor 81 can be almost ignored, the resistance value between the heater-and-thermistor shared lead pin P6 and the ground lead pin P7 is obtained as the resistance value R_{TH} of the thermistor 8.

In short, DC power can be applied only to the series body of the thermistor 8 and the inductor 81, and the resistance value R_{TH} of the thermistor 8 can be obtained.

Even when the temperature of the semiconductor laser 5 and the temperature of the optical monitor 6 are detected regularly, periodically, or randomly by the thermistor 8 during the operation of the optical module, the control unit 9 supplies a direct current between the heater-and-thermistor shared lead pin P6 and the ground lead pin P7.

By supplying a direct current between the heater-and-thermistor shared lead pin P6 and the ground lead pin P7, the resistance value R_{TH} of the thermistor 8 can be obtained without flowing a current through the series body of the heater 7 and the capacitor 71.

As described above, similarly to the optical module according to the first embodiment, the optical module according to the second embodiment has an effect that an optical module with enhanced functions can be downsized.

Furthermore, in the optical module according to the second embodiment, a current does not flow through the thermistor 8 at the time of heating by the heater 7, AC power can be applied only to the series body of the heater 7 and the capacitor 71, a current does not flow through the heater 7 at the time of measuring and detecting the temperature by the thermistor 8, DC power can be applied only to the series body of the thermistor 8 and the inductor 81, and the resistance value R_{TH} of the thermistor 8 can be obtained.

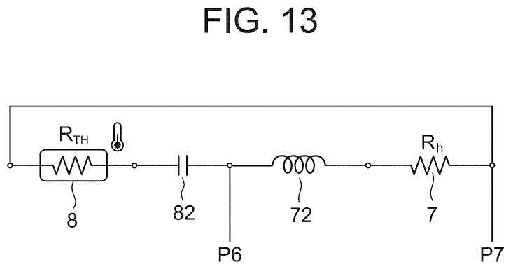

Note that, as illustrated in FIG. 13, in the optical module according to the first embodiment, the inductor 72 electrically connected in series with the heater 7 may be disposed between the heater-and-thermistor shared lead pin P6 and the ground node, and the capacitor 82 electrically connected in series with the thermistor 8 may be disposed between the heater-and-thermistor shared lead pin P6 and the ground node.

In a modification of the optical module according to the second embodiment illustrated in FIG. 13, when the control unit 9 supplies a direct current between the heater-and-thermistor shared lead pin P6 and the ground lead pin P7 in a manner that an alternating current that is a current with the target value Ih_target flows to the heater 7 during the operation of the optical module, DC power can be applied only to the series body of the heater 7 and the inductor 72, and the temperature of the ring resonator filter 64a can be adjusted without flowing a current through the series body of the thermistor 8 and the capacitor 82.

On the other hand, in a case where the temperature of the semiconductor laser 5 and the temperature of the optical monitor 6 are detected by the thermistor 8, when the control unit 9 supplies an alternating current between the heater-and-thermistor shared lead pin P6 and the ground lead pin P7, AC power can be applied only to the series body of the thermistor 8 and the capacitor 82, the resistance value R_{TH} of the thermistor 8 can be obtained without flowing an alternating current through the series body of the heater 7 and the inductor 72, and the temperature of the semiconductor laser 5 and the temperature of the optical monitor 6 can be detected and measured.

The modification of the optical module according to the second embodiment illustrated in FIG. 13 also has effects similar to those of the optical module according to the second embodiment.

Note that it is possible to freely combine the embodiments, modify any component of each embodiment, or omit any component of each embodiment.

### INDUSTRIAL APPLICABILITY

The optical module according to the present disclosure is suitable for an optical module used in a large-capacity optical communication system, particularly, an optical module used in a digital coherent communication system.

In addition, the optical module according to the present disclosure is suitable for a TO-CAN optical transmission module for optical communication including a single-wavelength semiconductor laser.

### REFERENCE SIGNS LIST

1: Package, 11: Stem, 12: Cap,, 13: Window, 2: Temperature controller, 3: Base, 4: Semiconductor laser submount, 5: Semiconductor laser, 6: Optical monitor, 61: Optical coupler, 62: Optical demultiplexer, 63: First optical receiver, 64: Optical filter, 65: Second optical receiver, 7: Heater, 71: Capacitor, 72: Inductor, 8: Thermistor, 81: Inductor, 82: Capacitor, 9: Control unit, P1 to P7: Lead pin

1. An optical module comprising:
a package including a stem and a windowed cap with a cylindrical shape, an open end surface of a side wall portion being fixed in contact with a peripheral end portion of an inner plane of the stem;
a semiconductor laser housed in the package, to emit a laser beam from a window of the windowed cap;
an optical monitor housed in the package, to receive a laser beam from the semiconductor laser and monitor a laser beam from the semiconductor laser;
a temperature controller housed in the package, to execute control to change a temperature applied to the semiconductor laser and the optical monitor when a monitored value from the optical monitor deviates from a set monitored value, and to adjust a temperature of the semiconductor laser and a temperature of the optical monitor;
a heater housed in the package;
a thermistor housed in the package, the thermistor being electrically connected in parallel with the heater;
a laser lead pin electrically insulated from and penetrating the stem, the laser lead pin having an inner lead portion exposed from the inner plane of the stem, the inner lead portion of the laser lead pin being connected to an electrode of the semiconductor laser;
a monitor lead pin electrically insulated from and penetrating the stem, the monitor lead pin having an inner lead portion exposed from the inner plane of the stem, the inner lead portion of the monitor lead pin being connected to an output terminal of the optical monitor;
a lead pin for a temperature controller electrically insulated from and penetrating the stem, the lead pin for the temperature controller having an inner lead portion exposed from the inner plane of the stem, the inner lead portion of the lead pin for the temperature controller being connected to an electrode of the temperature controller;
a heater-and-thermistor shared lead pin electrically insulated from and penetrating the stem, the heater-and-thermistor shared lead pin having an inner lead portion exposed from the inner plane of the stem, the inner lead portion of the heater-and-thermistor shared lead pin being connected to a first end of the heater and a first end of the thermistor; and
a ground lead pin electrically connected to the stem.

2. The optical module according to claim 1, wherein
the temperature controller is placed on the stem, and
the optical module comprising a base placed and fixed on a mounting surface of the temperature controller, the base including an erected surface portion having the semiconductor laser mounted and fixed on the erected surface portion, a plane portion formed integrally with the erected surface portion, the optical monitor being placed and fixed at a position on the plane portion where the optical monitor receives a backward laser beam from the semiconductor laser, and a stepped portion formed on an opposite side of an erected surface of the erected surface portion, and including a placement surface as a horizontal surface having the thermistor placed and fixed on the placement surface.

3. The optical module according to claim 1, wherein
the optical monitor includes a first optical receiver to receive a laser beam from the semiconductor laser, an optical filter to receive a laser beam from the semiconductor laser, and a second optical receiver to receive the laser beam via the optical filter, and
the monitor lead pin includes a lead pin having an output terminal of the first optical receiver connected to the lead pin, and a lead pin having an output terminal of the second optical receiver connected to the lead pin.

4. The optical module according to claim 1, wherein
the temperature controller is a thermo-electric cooler including a Peltier element having a positive electrode and a negative electrode, and
a lead pin for the temperature controller includes a lead pin having the positive electrode of the temperature controller connected to the lead pin, and a lead pin having the negative electrode of the temperature controller connected to the lead pin.

5. The optical module according to claim 1, wherein
the thermistor has a characteristic as a resistor whose resistance value changes depending on a temperature, and
in an operating temperature range of the semiconductor laser and the optical monitor, a resistance value of the thermistor is larger than a resistance value of the heater and is equal to or less than 70 times the resistance value of the heater.

6. The optical module according to claim 1, wherein
the thermistor has a characteristic as a resistor whose resistance value changes depending on a temperature,
the heater has a constant resistance value in an operating temperature range of the semiconductor laser and the optical monitor, and
in the operating temperature range, the thermistor has a resistance value larger than a resistance value of the heater, and a parallel resistance value of the thermistor and the heater changes by 0.1% or more per degree of temperature change with respect to a maximum value of the parallel resistance value of the thermistor and the heater in the operating temperature range.

7. The optical module according to claim 1, wherein
the optical monitor is a planar waveguide optical monitor including an optical coupler, an optical demultiplexer, a first optical receiver, an optical filter, and a second optical receiver, a monitored value from the optical monitor has a first monitored value and a second monitored value,
the first optical receiver receives a laser beam obtained by the optical coupler receiving a laser beam from the semiconductor laser and the optical demultiplexer demultiplexing the laser beam via an optical waveguide, photoelectrically converts the received laser beam, and outputs the first monitored value to an output terminal,
the second optical receiver receives a laser beam obtained by the optical coupler receiving a laser beam from the semiconductor laser and the optical filter filtering a laser beam demultiplexed by the optical demultiplexer, photoelectrically converts the received laser beam, and outputs the second monitored value to an output terminal,
the monitor lead pin includes a lead pin having the output terminal of the first optical receiver connected to the lead pin and a lead pin having the output terminal of the second optical receiver connected to the lead pin, and
the heater heats the optical monitor to adjust a temperature of the optical monitor.

8. The optical module according to claim 7, wherein
the thermistor has a characteristic as a resistor whose resistance value changes depending on a temperature,
in an operating temperature range of the semiconductor laser and the optical monitor, a resistance value of the thermistor is larger than a resistance value of the heater and is equal to or less than 70 times the resistance value of the heater.

9. The optical module according to claim 7, wherein
the thermistor has a characteristic as a resistor whose resistance value changes depending on a temperature,
the heater has a constant resistance value in an operating temperature range of the semiconductor laser and the optical monitor, and
in the operating temperature range, the thermistor has a resistance value larger than a resistance value of the heater, and a parallel resistance value of the thermistor and the heater changes by 0.1% or more per degree of temperature change with respect to a maximum value of the parallel resistance value of the thermistor and the heater in the operating temperature range.

10. The optical module according to claim 1, comprising:
a capacitor electrically connected in series with the heater between the heater-and-thermistor shared lead pin and a ground node; and
an inductor electrically connected in series with the thermistor between the heater-and-thermistor shared lead pin and the ground node.

11. The optical module according to claim 1, comprising:
an inductor electrically connected in series with the heater between the heater-and-thermistor shared lead pin and a ground node; and
a capacitor electrically connected in series with the thermistor between the heater-and-thermistor shared lead pin and the ground node.

12. The optical module according to claim 1, wherein the stem is a disk-shaped metal with a diameter of 5.6 mm, and the windowed cap has a cylindrical shape.
